(19) United States
(12) Patent Application Publication
(10) Pub. No.: US 2015/0311262 A1
(43) Pub. Date: Oct. 29, 2015

(54) ORGANIC LIGHT-EMITTING DIODE DISPLAY PANEL

(71) Applicant: Innolux Corporation, Chu-Nan (TW)

(72) Inventors: Shun-Hsi WANG, Chu-Nan (TW); Yu-Hao LEE, Chu-Nan (TW); Chien-Ping CHANG, Chu-Nan (TW); Wen-Hsien LIU, Chu-Nan (TW); Hung-Pin WENG, Chu-Nan (TW)

(73) Assignee: Innolux Corporation, Chu-Nan (TW)

(21) Appl. No.: 14/694,575

(22) Filed: Apr. 23, 2015

(30) Foreign Application Priority Data
Apr. 25, 2014 (TW) 103114967

(51) Int. Cl. H01L 27/32; H01L 51/52; H01L 51/50

(52) U.S. Cl. CPC H01L 27/3213; H01L 27/3209; H01L 51/504; H01L 51/5278

(57) ABSTRACT

An organic light-emitting diode (OLED) display panel is provided. The OLED display panel includes a pixel. The pixel includes a first sub-pixel and a second sub-pixel. The first sub-pixel includes a first light emitting unit and a second light emitting unit. The first light emitting unit is used for emitting a first color light. The second light emitting unit is used for emitting a second color light. The second sub-pixel includes a third light emitting unit and a fourth light emitting unit. The third light emitting unit is used for emitting a third color light. The fourth light emitting unit is used for emitting a fourth color light. The combination of the first color light and the second color light is different from the combination of the third color light and the fourth color light.

This application claims the benefit of Taiwan application Serial No. 103114967, filed Apr. 25, 2014, the disclosure of which is incorporated by reference herein in its entirety.

### TECHNICAL FIELD

The disclosure relates in general to display panel, and more particularly to an organic light-emitting diode (OLED) display panel.

### BACKGROUND

As the development of the display technology, various display panels are invented. An organic light-emitting diode (OLED) has a characteristic of self-emissive, and has advantages of fast response, light weight, thin volume and flexible. Therefore, the OLED display panel becomes a target of technology development.

In an OLED display panel, technologies of a combination of a Fine Metal Shadow Mask (FMM) and a Pentile arrangement, a Laser Induced Thermal Imaging (LITI), and a combination of a white OLED and a color filter can increase the resolution of the display panel.

However, those aforementioned techniques have their drawbacks and processing bottleneck. For example, the combination of the FMM and the Pentile arrangement is limited by the finesse and the reliability of the FMM. The resolution of the display panel is fictitious, so that the edge of words may be unclear.

In LITI, the power consumption is high. When the organic material is heated, it is easily broken, so that the life expectancy is reduced and the yield rate is reduced.

Furthermore, in the combination of the white OLED and the color filter, some of the light will be absorbed by the color filter for displaying a frame which is not white. Also, uniformity is a challenge for a large display panel.

Therefore, how to increase the resolution of the OLED display panel, reduce the difficulty of the process and prolong the life of the panel is a current focus of research and development.

### SUMMARY

The disclosure is directed to an organic light-emitting diode (OLED) display panel. Light emitting units whose colors are different are stacked in one sub-pixel, such that the resolution can be increase and the life can be prolonged.

According to one embodiment, an organic light-emitting diode (OLED) display panel is provided. The OLED display panel comprises a first pixel. The first pixel includes a first sub-pixel and a second sub-pixel. The first sub-pixel includes a first light emitting unit and a second light emitting unit. The first light emitting unit is for emitting a first color light. The second light emitting unit is for emitting a second color light. The second light emitting unit and the first light emitting unit are stacked. The second sub-pixel includes a third light emitting unit and a fourth light emitting unit. The third light emitting unit is for emitting a third color light. The fourth light emitting unit is for emitting fourth color light. The fourth light emitting unit and the third light emitting unit are stacked. A combination of the first color light, the second color light, the third color light and the fourth color light comprises a red light, a green light and a blue light. A combination of the first color light and the second color light is different from a combination of the third color light and the fourth color light.

### BRIEF DESCRIPTION OF THE DRAWINGS

FIG. 1 shows an organic light-emitting diode (OLED) display panel according to a first embodiment.

FIG. 2 shows an OLED display panel according to a second embodiment.

FIG. 3 shows an OLED display panel according to a third embodiment.

FIG. 4 shows an OLED display panel according to a fourth embodiment.

FIG. 5 shows an OLED display panel according to a fifth embodiment.

FIG. 6 shows an OLED display panel according to a sixth embodiment.

In the following detailed description, for purposes of explanation, numerous specific details are set forth in order to provide a thorough understanding of the disclosed embodiments. It will be apparent, however, that one or more embodiments may be practiced without these specific details.

In other instances, well-known structures and devices are schematically shown in order to simplify the drawing.

### DETAILED DESCRIPTION

### First Embodiment

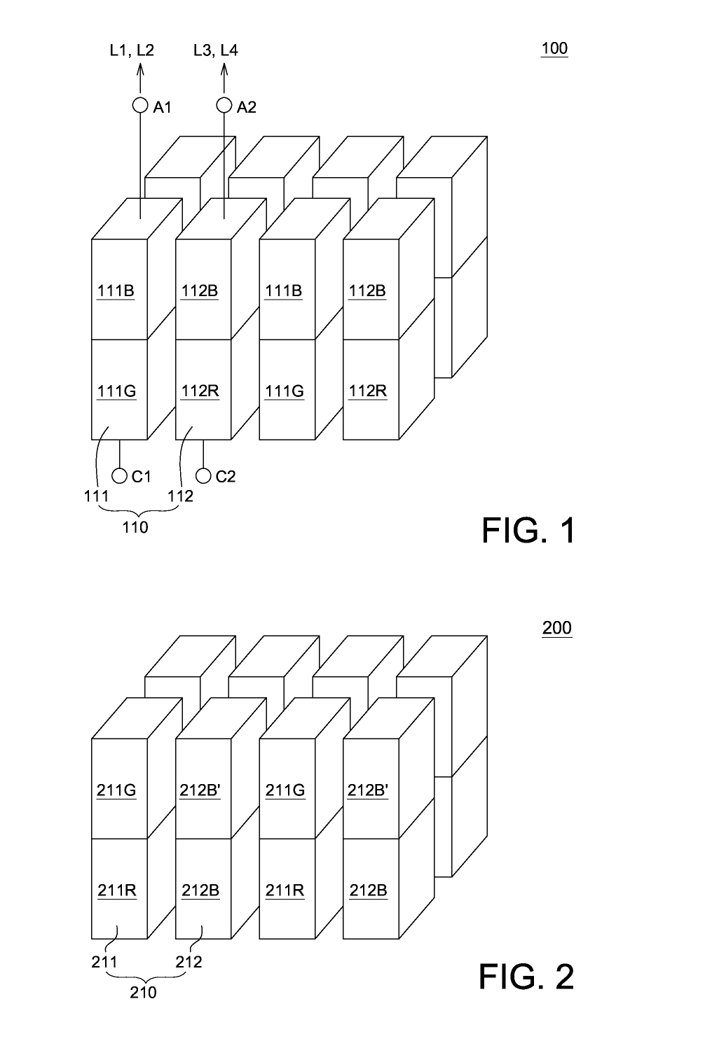

Please refer to FIG. 1, which shows an organic light-emitting diode

(OLED) display panel 100 according to a first embodiment. The OLED display panel 100 includes a plurality of pixels 110. The pixels 110 are arranged in a matrix. Each pixel 110 can display three primary colors, such as red color, green color and blue color.

In the present embodiment, the pixel 110 includes a first sub-pixel 111 and a second sub-pixel 112. The first sub-pixel 111 is used for displaying one of the three primary colors. The second sub-pixel 112 is used for displaying one of the three primary colors.

In the present embodiment, the first sub-pixel 111 includes a first light emitting unit 111G and a second light emitting unit 111B. The first light emitting unit 111G is used for emitting a first color light L1, such as a green light. The second light emitting unit 111B is used for emitting a second color light L2, such as a blue light. The second light emitting unit 111B and the first light emitting unit 111G are stacked. For example, the second light emitting unit 111B is stacked on the first light emitting unit 111G. In another embodiment, the first light emitting unit 111G may be stacked on the second light emitting unit 111B.

In the present embodiment, the second sub-pixel 112 includes a third light emitting unit 112R and a fourth light emitting unit 112B. The third light emitting unit 112R is used for emitting a third color light L3, such as a red light. The fourth light emitting unit 112B is used for emitting a fourth color light L4, such as a blue light. The fourth light emitting unit 112B and the third light emitting unit 112R are stacked. For example, the fourth light emitting unit 112B is stacked on the third light emitting unit 112R. In another embodiment, the third light emitting unit 112R may be stacked on the fourth light emitting unit 112B. The first light emitting unit 111G, the second light emitting unit 111B, the third light emitting unit 112R and the fourth light emitting unit 112B are stacked and extended along three dimensions.

For displaying three primary colors by the pixel 110, the first color light L1, the second color light L2, the third color light L3 and the fourth color light L4 comprise the red light, the green light and the blue light. For example, the third color light L3 is the red light, the first color light L1 is the green light, and the second color light L2 and the fourth color light L4 are the blue lights.

In the present embodiment, a combination of the first color light L1 and the second color light L2 is different from a combination of the third color light L3 and the fourth color light L4. For example, a combination of the first color light L1 and the second color light L2 is the green light and the blue light. A combination of the third color light L3 and the fourth color light L4 is the red light and the blue light. The tow combinations are different.

Regarding the driving operation of the pixel 110, the first sub-pixel 111 includes a first anode A1 and a first cathode C1. The first anode Al and the first cathode C1 are used for driving the first light emitting unit 111G and the second light emitting unit 111B. That is to say, the first light emitting unit 111 G and the second light emitting unit 111 B share the first anode A1 and the first cathode C1. In another embodiment, the location of the first anode A1 and the location of the first cathode C1 can be exchanged. The second sub-pixel 112 includes a second anode A2 and a second cathode C2. The second anode A2 and the second cathode C2 are used for driving the third light emitting unit 112R and the fourth light emitting unit 112B. That is to say, the third light emitting unit 112R and the fourth light emitting unit 112B share the second anode A2 and the second cathode C2. In another embodiment, the location of the second anode A2 and the location of the second cathode C2 can be exchanged.

During the driving operation, the first sub-pixel 111 only lights on one of the first light emitting unit 111G and the second light emitting unit 111B by the first anode A1 and the first cathode C1. For example, the first sub-pixel 111 may only light on the first light emitting unit 111G to emit the green light. Or, the first sub-pixel 111 may only light on the second light emitting unit 111B to emit the blue light. The first sub-pixel 111 does not simultaneously light on the first light emitting unit 111G and the second light emitting unit 111B, such that the green light and the blue light will not be mixed. In each sub-pixel, only one light emitting unit can be lighted on at the same time. If a predetermined color which is not one of the three primary colors is needed, the sub-pixel can emit different primary color lights in turn by DC or AC power. Due to the visual persistence, people can see a predetermined color light in his eyes.

The second sub-pixel 112 only light on one of the third light emitting unit 112R and the fourth light emitting unit 112B by the second anode A2 and the second cathode C2. For example, the second sub-pixel 112 can only light on the third light emitting unit 112R to emit the red light. Or, the second sub-pixel 112 may only light on the fourth light emitting unit 112B to emit the blue light. The second sub-pixel 112 does not simultaneously light on the third light emitting unit 112R and the fourth light emitting unit 112B, such that the red light and the blue light will not be mixed. In each sub-pixel, only one light emitting unit can be lighted on at the same time. If a predetermined color which is not one of the three primary colors is needed, the sub-pixel can emit different primary color lights in turn. Due to the visual persistence, people can see a predetermined color light in his eyes.

In the present embodiment, the second color light L2 is identical to the fourth color light L4. For example the second color light L2 and the fourth color light L4 are both blue light. The first color light L1 is different from the third color light L3. For example, the first color light L1 is the green light and the third color light L3 is the red light. The second color light L2 and the fourth color light L4 are not limited to be the blue light. In another embodiment, the second color light L2 and the fourth color light L4 may be the red light or the green light.

If the pixel 110 is needed to display the green color, then the first light emitting unit 111G can be lighted on. If the pixel 110 is needed to display the red color, then the third light emitting unit 112R can be lighted on. If the pixel 110 is needed to display the blue color, then both of the second light emitting unit 111B and the fourth light emitting unit 112B can be lighted on. Because both of the second light emitting unit 111B and the fourth light emitting unit 112B can emit the blue lights, the driving voltage of each of the second light emitting unit 111B and the fourth light emitting unit 112B can be 50% of the driving voltage of the first light emitting unit 111G or the third light emitting unit 112R. As such, the power consumption of the OLED display panel 100 can be reduced when it displays blue color and the life of the OLED display panel 100 can be prolonged.

In the present embodiment, two sub-pixels, such as the first sub-pixel 111 and the second sub-pixel 112, can display three primary colors without any additional one sub-pixel. As such, the amount of the pixels of the OLED display panel 100 and the resolution can be increased by more than 33%.

Moreover, during the manufacturing process, the first light emitting unit 111G and the third light emitting unit 112R can be formed by two masks. During the manufacturing process, the same material can be sputtered on whole of the surface to form the second light emitting unit 111B and the fourth light emitting unit 112B without any mask, because the second color light L2 and the fourth color light L4 are identical. The pixel 110 having three primary colors can be formed by two masks used in two sputtering processes, as such the variation and cost can be reduced.

### Second Embodiment

Please refer to FIG. 2, which shows an OLED display panel 200 according to a second embodiment. The difference between the OLED display panel 200 and the OLED display panel 100 is that the combination of the color lights of a first light emitting unit 211R, a second light emitting unit 211G, a third light emitting unit 212B and a fourth light emitting unit 212B′. Other similarities will not be repeated here.

In the present embodiment, the first light emitting unit 211R is used for emitting the red light, the second light emitting unit 211G is used for emitting the green light, the third light emitting unit 212B is used for emitting the blue light, and the fourth light emitting unit 212B′ is used for emitting the blue light. The color of the color light emitted from the first light emitting unit 211R and the color of the color light emitted from the second light emitting unit 211G can be exchanged. The color light emitted from the third light emitting unit 212B and the color light emitted from the fourth light emitting unit 212B′ are not limited to be the blue light. In another embodiment, the third color light L3 and the fourth color light L4 can be the red light, or the third color light L3 and the fourth color light L4 can be the green light.

If the pixel 210 is needed to be display the red color, then the first light emitting unit 211R can be lighted on. If the pixel 210 is needed to be displayed the green color, then the second light emitting unit 211G can be lighted on. If the pixel 210 is needed to be displayed the blue color, then the third light emitting unit 212B and the fourth light emitting unit 212B′ can be simultaneously lighted on. Because both of the third light emitting unit 212B and the fourth light emitting unit 212B′can emit the blue lights, the driving voltage of each of the third light emitting unit 212B and the fourth light emitting unit 212B′ can be 50% of the driving voltage of the first light emitting unit 211R or the second light emitting unit 211G. As such, the power consumption of the OLED display panel 200 can be reduced when it displays blue color and the life of the OLED display panel 200 can be prolonged.

In the present embodiment, two sub-pixels, such as the first sub-pixel 211 and the second sub-pixel 212, can display three primary colors without any additional one sub-pixel. As such, the amount of the pixels of the OLED display panel 100 and the resolution can be increased by more than 33%.

Moreover, during the manufacturing process, the first light emitting unit 211R and the third light emitting unit 212B can be formed by two masks.

During the manufacturing process, the second light emitting unit 211G and the fourth light emitting unit 212B′ can be formed by the two masks which is used for forming the first light emitting unit 211R and the third light emitting unit 212B. The pixel 110 having three primary colors can be formed by two masks, as such the difficulty can be reduced.

### Third Embodiment

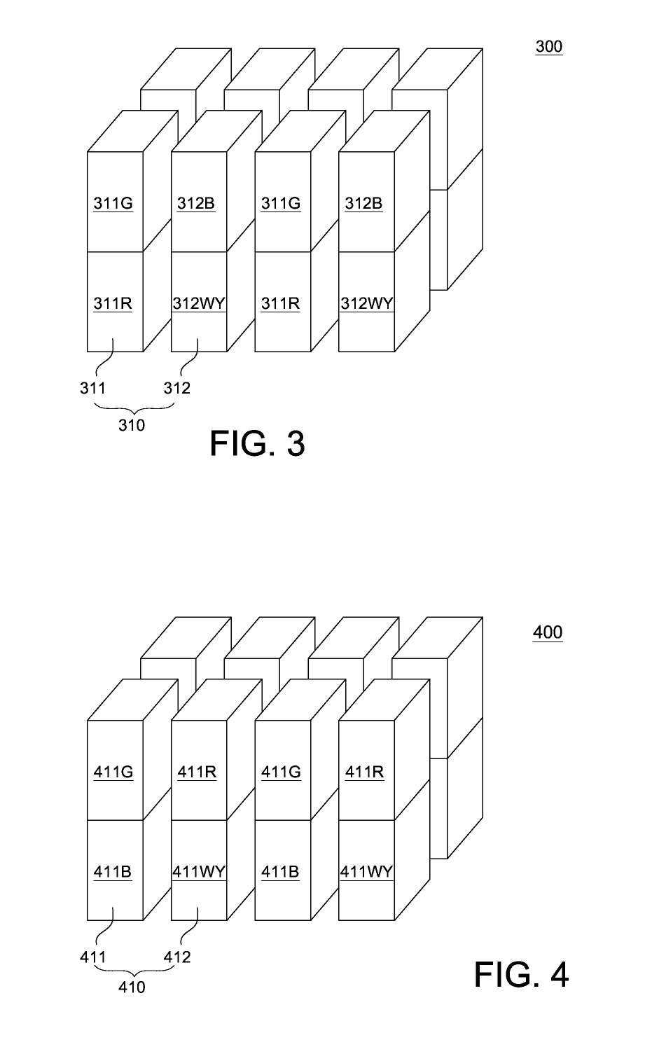

Please refer to FIG. 3, which shows an OLED display panel 300 according to a third embodiment. The difference between the OLED display panel 300 and the OLED display panel 100 is that the combination of the color lights of a first light emitting unit 311R, a second light emitting unit 311G, a third light emitting unit 312WY and a fourth light emitting unit 312B. Other similarities will not be repeated here.

In the present embodiment, the first light emitting unit 311R is used for emitting the red light, the second light emitting unit 311G is used for emitting the green light, the third light emitting unit 312WY is used for emitting the white light or the yellow light which is complementary to the white light, and the fourth light emitting unit 312B is used for emitting the blue light. In the other embodiments, the stacking relationship is not limited thereto.

If the pixel 310 is needed to be displayed the red color, then the first light emitting unit 311R can be lighted on. If the pixel 310 is needed to be displayed the green color, then the second light emitting unit 311G can be lighted on. If the pixel 310 is needed to be displayed the blue color, then the fourth light emitting unit 312B can be lighted on. If the pixel 310 is needed to be displayed the white color or the yellow color, then the third light emitting unit 312WY can be lighted on.

In the present embodiment, two sub-pixels, such as the first sub-pixel 311 and the second sub-pixel 312, can display three primary colors without any additional one sub-pixel. As such, the amount of the pixels of the OLED display panel 300 and the resolution can be increased by more than 33%.

Moreover, during the manufacturing process, the first light emitting unit 311R and the second light emitting unit 311G can be formed by one mask.

During the manufacturing process, the third light emitting unit 312WY and the fourth light emitting unit 312B can be formed by another mask. The pixel 310 having three primary colors can be formed by two masks, as such the variation and cost can be reduced.

### Fourth Embodiment

Please refer to FIG. 4, which shows an OLED display panel 400 according to a second embodiment. The difference between the OLED display panel 200 and the OLED display panel 100 is that the combination of the color lights of a first light emitting unit 411B, a second light emitting unit 411G, a third light emitting unit 411WY and a fourth light emitting unit 411R. Other similarities will not be repeated here.

In the present embodiment, the first light emitting unit 411B is used for emitting the blue light, the second light emitting unit 411G is used for emitting the green light, the third light emitting unit 411WY is used for emitting the white light or the yellow light which is complementary to the white light, the fourth light emitting unit 411R is used for emitting the red light.

If the pixel 410 is needed to display the blue color, then the first light emitting unit 411B can be lighted on. If the pixel 410 is needed to display the green color, then the second light emitting unit 411G can be lighted on. If the pixel 410 is needed to display the red color, then the fourth light emitting unit 411R can be lighted on. If the pixel 410 is needed to display the white color or the yellow color, then the third light emitting unit 411WY can be lighted on.

In the present embodiment, two sub-pixels, such as the first sub-pixel 411 and the second sub-pixel 412, can display three primary colors without any additional one sub-pixel. As such, the amount of the pixels of the OLED display panel 400 and the resolution can be increased by more than 33%.

Moreover, during the manufacturing process, the first light emitting unit 411B and the second light emitting unit 411G can be formed by one mask. During the manufacturing process, the third light emitting unit 411WY and the fourth light emitting unit 411R can be formed by another mask. The pixel 410 having three primary colors can be formed by two masks, as such the variation and cost can be reduced.

### Fifth Embodiment

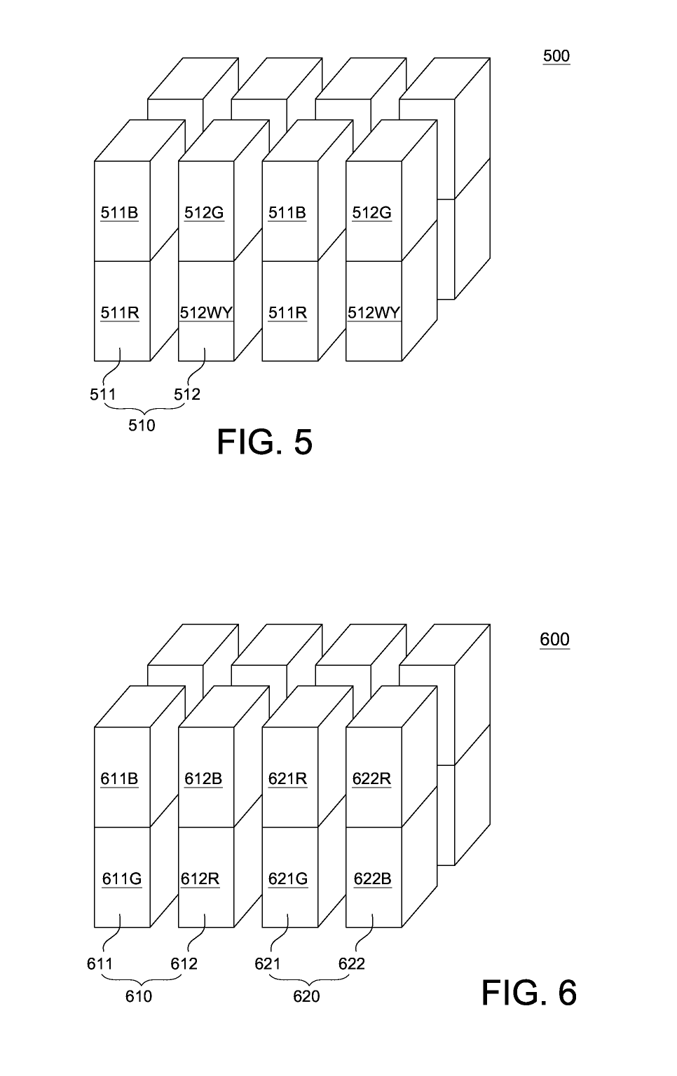

Please refer to FIG. 5, which shows an OLED display panel 500 according to a fifth embodiment. The difference between the OLED display panel 200 and the OLED display panel 100 is that the combination of the color lights of a first light emitting unit 511R, a second light emitting unit 511B, a third light emitting unit 512WY and a fourth light emitting unit 512G. Other similarities will not be repeated here.

In the present embodiment, the first light emitting unit 511B is used for emitting the red light, the second light emitting unit 511B is used for emitting the blue light, the third light emitting unit 512WY is used for emitting the white color or the yellow light which is complementary to the white light, and the fourth light emitting unit 512G is used for emitting the green light.

If the pixel 510 is needed to display the red color, then first light emitting unit 511R can be lighted on. If the pixel 510 is needed to be display the blue color, then the second light emitting unit 511B can be lighted on. If the pixel 510 is needed to be display the green color, then the fourth light emitting unit 512G can be lighted on. If the pixel 510 is needed to be displayed the white color or the yellow color, then third light emitting unit 512WY can be lighted on.

In the present embodiment, two sub-pixels, such as the first sub-pixel 511 and the second sub-pixel 512, can display three primary colors without any additional one sub-pixel. As such, the amount of the pixels of the OLED display panel 500 and the resolution can be increased by more than 33%.

Moreover, during the manufacturing process, the first light emitting unit 511R and the second light emitting unit 511B can be formed by one mask. During the manufacturing process, the third light emitting unit 512W and the fourth light emitting unit 512G can be formed by another mask. The pixel 510 having three primary colors can be formed by two masks, as such the variation and cost can be reduced.

### Sixth Embodiment

Please refer to FIG. 6, which shows an OLED display panel 600 according to a sixth embodiment. The difference between the OLED display panel 600 and the OLED display panel 100 is the arrangement among the pixels, such as a first pixel 610 and a second pixel 620. Other similarities will not be repeated here.

In the present embodiment, the OLED display panel 600 includes a plurality of first pixels 610 and a plurality of second pixels 620. Each first pixel 610 includes a first sub-pixel 611 and a second sub-pixel 612. The first sub-pixel 611 includes a first light emitting unit 611G and a second light emitting unit 611B. Each second sub-pixel 612 includes a third light emitting unit 612R and a fourth light emitting unit 612B. The second pixel 620 includes a third sub-pixel 621 and a fourth sub-pixel 622. The third sub-pixel 621 includes a fifth light emitting unit 621G and a sixth light emitting unit 621R. The fourth sub-pixel 622 includes a seventh light emitting unit 622B and an eighth light emitting unit 622R.

The first light emitting unit 611G is used for emitting the green light, the second light emitting unit 611B is used for emitting the blue light, the third light emitting unit 612R is used for emitting the red light, the fourth light emitting unit 612B is used for emitting the blue light, the fifth light emitting unit 621G is used for emitting the green light, the sixth light emitting unit 621R is used for emitting the red light, the seventh light emitting unit 622B is used for emitting the blue light, and the eighth light emitting unit 622R is used for emitting the red light.

If the first pixel 610 is needed to display the green color, then the first light emitting unit 611G can be lighted on. If the first pixel 610 is needed to display the red color, then the third light emitting unit 612R can be lighted on. If the first pixel 610 is needed to display the blue color, then the second light emitting unit 611B and the fourth light emitting unit 612B can be lighted on. Because both of the second light emitting unit 611B and the fourth light emitting unit 612B can emit the blue lights, the driving voltage of each of the second light emitting unit 611B and the fourth light emitting unit 612B can be 50% of the driving voltage of the first light emitting unit 611G or the third light emitting unit 612R. If the second pixel 620 is needed to display the green color, then the fifth light emitting unit 621G can be lighted on. If the second pixel 620 is needed to display the blue color, then the seventh light emitting unit 622B can be lighted on. If the second pixel 620 is needed to display the red color, then the sixth light emitting unit 621R and the eighth light emitting unit 622R can be lighted on. Because both of the sixth light emitting unit 621R and the eighth light emitting unit 622R can emit the blue lights, the driving voltage of each of the sixth light emitting unit 621R and the eighth light emitting unit 622R can be 50% of the driving voltage of the fifth light emitting unit 621G or the seventh light emitting unit 622B. As such, the power consumption of the OLED display panel 600 can be reduced when it displays blue color and the life of the OLED display panel 600 can be prolonged.

In the first pixel 610 of the present embodiment, two sub-pixels, such as the first sub-pixel 611 and the second sub-pixel 612, can display three primary colors without any additional one sub-pixel. In the second pixel 620 of the present embodiment, two sub-pixels, such as the third sub-pixel 621 and the fourth sub-pixel 622, can display three primary colors without any additional one sub-pixel. As such, the amount of the pixels of the OLED display panel 600 and the resolution can be increased by more than 33%.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An organic light-emitting diode (OLED) display panel, comprising:
a first pixel, including:
a first sub-pixel, including:
a first light emitting unit for emitting a first color light; and
a second light emitting unit for emitting a second color light, the second light emitting unit and the first light emitting unit being stacked; and
a second sub-pixel, including:
a third light emitting unit for emitting a third color light; and
a fourth light emitting unit for emitting a fourth color light, the fourth light emitting unit and the third light emitting unit being stacked;
wherein a combination of the first color light, the second color light, the third color light and the fourth color light comprises a red light, a green light and a blue light;
a combination of the first color light and the second color light is different from a combination of the third color light and the fourth color light.

2. The OLED display panel according to claim 1, wherein the second light emitting unit is stacked on the first light emitting unit, and the fourth light emitting unit is stacked on the third light emitting unit.

3. The OLED display panel according to claim 2, wherein the second color light is identical to the fourth color light.

4. The OLED display panel according to claim 3, wherein the first color light is different from the third color light.

5. The OLED display panel according to claim 1, wherein the first color light is identical to the second color light.

6. The OLED display panel according to claim 1, wherein the first color light is different from the second color light, and the third color light is different from the fourth color light.

7. The OLED display panel according to claim 1, wherein the first color light, the second color light, the third color light or the fourth color light is a white light; or the first color light, the second color light, the third color light or the fourth color light is a yellow light.

8. The OLED display panel according to claim 5, wherein the first color light, the second color light, the third color light and the fourth color light are different.

9. The OLED display panel according to claim 1, wherein the first sub-pixel further includes a first anode and a first cathode, the first anode and the first cathode are used for driving one of the first light emitting unit and the second light emitting unit, and the second sub-pixel further includes a second anode and a second cathode, and the second anode and the second cathode are used for driving one of the third light emitting unit and the fourth light emitting unit.

10. The OLED display panel according to claim 1, further comprising:
a second pixel, including:
a third sub-pixel, including:
a fifth light emitting unit for emitting a fifth color light; and
a sixth light emitting unit for emitting a sixth color light, the sixth light emitting unit being stacked on the fifth light emitting unit, and
a fourth sub-pixel, including:
a seventh light emitting unit for emitting a seventh color light; and
an eighth light emitting unit for emitting an eighth color light, the eighth light emitting unit being stacked on the seventh light emitting unit;
wherein a combination of the fifth color light, the sixth color light, the seventh color light and the eighth color light comprises the red light, the green light and the blue light;
a combination of the fifth color light and the sixth color light is different from a combination of the seventh color light and the eighth color light;
a combination of the fifth color light, the sixth color light, the seventh color light and the eighth color light is different from a combination of the first color light, the second color light, the third color light and the fourth color light.
